(19) United States
(12) Patent Application Publication
(10) Pub. No.: US 2003/0164780 A1
(43) Pub. Date: Sep. 4, 2003

(54) Workstation-type notebook computer capable of switching key-in devices and output display monitors

(76) Inventor: Jefferson Liu, Taichung (TW)

Correspondence Address: Keith Kline, PRO-TECHTOR INTERNATIONAL, 20775 Norada Court, Saratoga, CA, 95070-3018, US

(21) Appl. No.: 10/382,270

(22) Filed: Mar. 4, 2003

(30) Foreign Application Priority Data
Mar. 4, 2002 (TW) 91202461

(51) Int. Cl. H03M 11/00; H03K 17/94; H04L 17/02

(52) U.S. Cl. 341/22; 341/176

(57) ABSTRACT

A workstation-type notebook computer capable of switching key-in devices and output display monitors comprises a motherboard, a key-in device, and a wireless audio-video (AV) signal transmitter. The key-in device is either of a keyboard, a touch-control panel, a mouse, and a joystick. The key-in device can be either built-in and therefore inseparable from the computer or separable from the computer by being disconnected at an input interface module. The wireless AV signal transmitter, used together with a wireless AV signal receiver, transmits the contents of an output AV signal from the motherboard to an external large-scaled display monitor that the wireless AV signal receiver is connected to.

### FIELD OF THE INVENTION

The present invention relates to a portable computer, particular to a workstation-type notebook computer that integrates the convenience of the conventional notebook computers and the advantages of the conventional workstation computers.

### BACKGROUND OF THE INVENTION

In spite of its portability, the conventional notebook computers are not easy to use in many situations. For example, running a computer game usually requires a large video display and a special control device, which are absent in a conventional notebook computer. Take another example; typing text materials on a notebook computer for a long period of time is painful, because the keyboard is too small. Based on its portability, the structure of a conventional notebook computer is intrinsically short of the size in display and key-in device. This present invention aims at overcoming the shortcomings of the conventional notebook computers, so that the convenience of the conventional notebook computers and the advantages of the conventional workstation computers are integrated; we therefore call it a workstation-type notebook computer.

### SUMMARY OF THE INVENTION

Accordingly, the primary object of the present invention is to provide a workstation-type notebook computer that integrating the convenience of the conventional notebook computers and the advantages of the conventional workstation-type computers.

To achieve the above object, the present invention provides a workstation-type notebook computer capable of switching key-in devices and output display monitors that comprises a motherboard, a key-in device, and a wireless audio-video (AV) signal transmitter; the key-in device being either of a keyboard, a touch-control panel, a mouse, and a joystick. Further, the key-in device can be either built-in and therefore inseparable from the computer or separable from the computer by being disconnected at an input interface module. The wireless AV signal transmitter, used together with a wireless AV signal receiver, transmits the contents of an output AV signal from the motherboard to an external large-scaled display monitor that the wireless AV signal receiver is connected to.

As the key-in device (either of a keyboard, a touch-control panel, a mouse, and a joystick) is inseparable, the present invention of a workstation-type notebook computer may further includes an external input interface module for receiving electrical signals from a second external key-in device (either of a keyboard, a touch-control panel, a mouse, and a joystick).

As the key-in device (either of a keyboard, a touch-control panel, a mouse, and a joystick) is separable, the present invention of a workstation-type notebook computer includes an input interface module for receiving electrical signals from the separable key-in device.

The various objects and advantages of the present invention will be more readily understood from the following detailed description when read in conjunction with the appended figures.

### BRIEF DESCRIPTION OF THE DRAWINGS

FIG. 1 shows the system block diagram of the workstation-type notebook computer of the present invention.

FIG. 2 shows the system block diagram of the workstation-type notebook computer of the present invention wherein the key-in device (either of a keyboard, a touch-control panel, a mouse, and a joystick) is inseparable.

FIG. 3 shows the system block diagram of the workstation-type notebook computer of the present invention wherein the key-in device (either of a keyboard, a touch-control panel, a mouse, and a joystick) is separable.

### DETAILED DESCRIPTION OF THE PREFERRED EMBODIMENTS

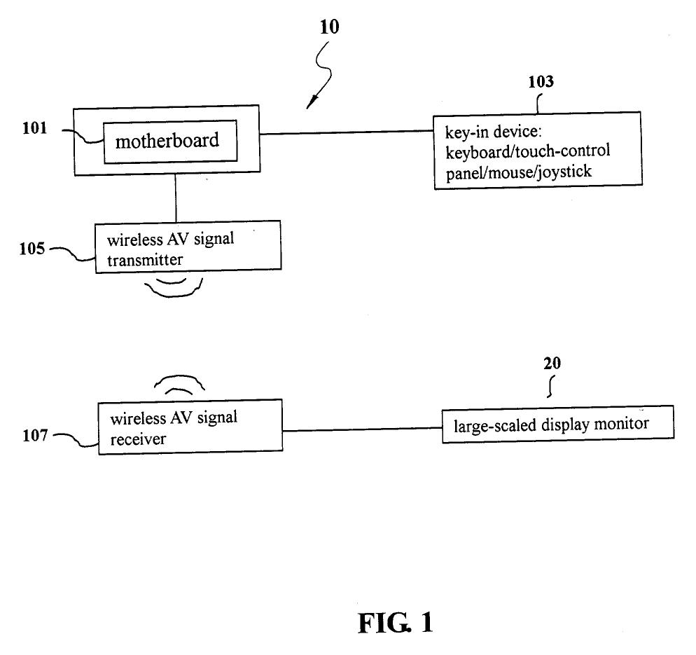

FIG. 1 shows the system block diagram of the workstation-type notebook computer of the present invention. The workstation-type notebook computer 10 of the present invention includes a motherboard 101 and a key-in device 103 (either of a keyboard, a touch-control panel, a mouse, and a joystick). The key-in device 103 (either of a keyboard, a touch-control panel, a mouse, and a joystick) can be separable or inseparable from the motherboard 101. A separable key-in device 103 (either of a keyboard, a touch-control panel, a mouse, and a joystick) means that a user can disassemble it from the main body of the workstation-type notebook computer 10. An inseparable key-in device 103 (either of a keyboard, a touch-control panel, a mouse, and a joystick) is installed permanently in the main body of the workstation-type notebook computer 10. The workstation-type notebook computer 10 further includes a wireless audio-video (AV, hereafter) signal transmitter 105 that transmits the contents of the output AV signal from the motherboard 101 wirelessly to a wireless AV signal receiver 107; the wireless AV signal receiver 107 is connected to a large-scaled display monitor 20 so that the output AV signal of the computer can be displayed thereon.: The output AV signal from the motherboard 101 to the wireless AV signals transmitter 105 is the same as the output AV signal to the built-in LCD display and speakers of the workstation-type notebook computer 10. The output AV signal may be alternatively channeled to the wireless AV signal transmitter 105 for being transmitted to the wireless AV signal receiver 107, so that the output AV signal can be displayed on the external large-scaled display monitor 20. It is a further function that the built-in LCD display of the workstation-type notebook computer 10 may be switched off when the output AV signal is displayed by the large-scaled display monitor 20, for saving electric power.

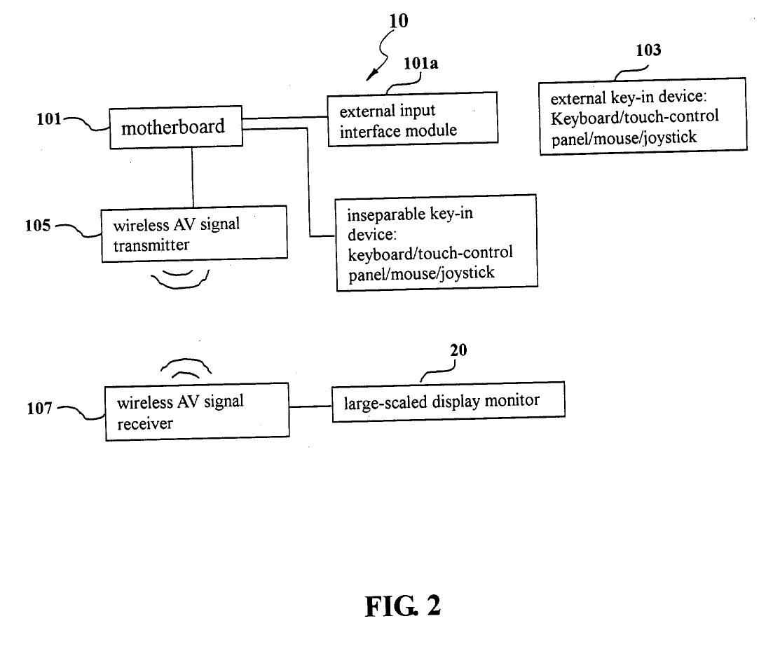

FIG. 2 shows an embodiment of the present invention wherein the key-in device (either of a keyboard, a touch-control panel, h mouse, and a joystick) is built into the computer and therefore inseparable. To use the computer with a second external key-in device 103 (either of a keyboard, a touch-control panel, a mouse, and a joystick), an external input interface module 101a is further installed in the computer, for receiving the electrical signals sent by an external key-in device 103 (either of a keyboard, a touch-control panel, a mouse, and a joystick). As the external key-in device 103 (either of a keyboard, a touch-control panel, a mouse, and a joystick) sends signal through a cable wire, the external input interface module 101a accepts signal from those standard specifications such as PS2, USB, etc. As the external key-in device 103 (either of a keyboard, a touch-control panel, a mouse, and a joystick) is wireless, the external input interface module 101a can be connected to a receiver through a standard signal such as PS2, USB, etc.; the receiver receives radio signals from a wireless external key-in device 103 (either of a keyboard, a touch-control panel, a mouse, and a joystick).

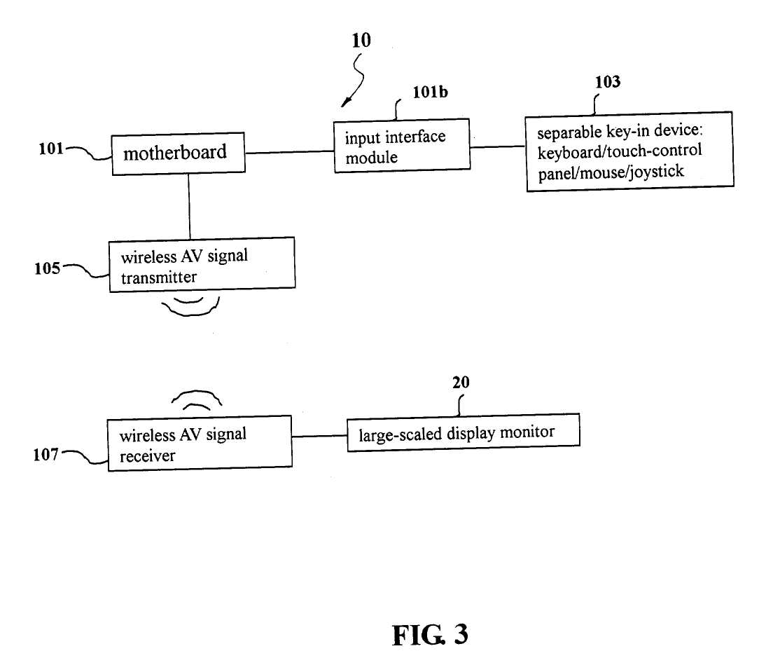

FIG. 3 shows an embodiment of the present invention wherein the key-in device 103 (either of a keyboard, a touch-control panel, a mouse, and a joystick) is separable. Compared with the embodiment shown in FIG. 1, the workstation-type notebook computer 10 shown in FIG. 3 further includes an input interface module 101b for receiving the electrical signals sent by a separable key-in device 103 (either of a keyboard, a touch-control panel, a mouse, and a joystick) through a cable wire. The electrical signals generated in the separable key-in device 103 (either of a keyboard, a touch-control panel, a mouse, and a joystick) are sent to the input interface module 101b by a standard signal such as PS2, USB, etc. Alternatively, the electrical signals generated in the separable key-in device 103 (either of a keyboard, a touch-control panel, a mouse, and a joystick) may be sent to the input interface module 101b wirelessly. The specification of the wireless transmission used by the key-in device 103 (either of a keyboard, a touch-control panel, a mouse, and a joystick) can be any standard radio transmission means, as long as the receiving end of the means is contained in the input interface module 101b.

The large-scaled display monitor 20 used with the present invention can be a television set, a cathodes-ray tube display monitor, or a display monitor of any other kind.

Although the present invention is disclosed by the above embodiments, it is obvious that the same invention may be varied in many ways. If all such modifications are obvious to one skilled in the art, they should not to be regarded as a departure from the spirit and scope of the present invention, and therefore should be included within the scope of the following claims.

What is claimed is:

1. A workstation-type notebook computer capable of switching key-in devices and output display monitors comprising
a motherboard,
a key-in device being one of a keyboard, a touch-control panel, a mouse, and a joystick, and
a wireless audio-video (AV, hereafter) signal transmitter, used together with a wireless AV signal receiver, for transmitting the contents of an output AV signal from said motherboard to an external large-scaled display monitor; said wireless AV signal receiver being connected to said large-scaled display monitor.

2. The workstation-type notebook computer of claim 1 wherein said key-in device is built-in and therefore inseparable from said computer, and an external input interface module is installed for receiving the electrical signals from a second external key-in device which is selected from one a keyboard, a touch-control panel, a mouse, and a joystick.

3. The workstation-type notebook computer of claim 2 wherein said second external key-in device transmits electrical signals generated therein to said external input interface module by a cable.

4. The workstation-type notebook computer of claim 2 wherein said second external key-in device transmits electrical signals generated therein to said external input interface module by a wireless means.

5. The workstation-type notebook computer of claim 1 wherein said key-in device is separable from said computer, and an input interface module is installed for receiving the electrical signals from said separable key-in device.

6. The workstation-type notebook computer of claim 5 wherein said separable key-in device transmits electrical signals generated therein to said input interface module by a cable.

7. The workstation-type notebook computer of claim 5 wherein said separable key-in device transmits electrical signals generated therein to said input interface module by a wireless means.

8. The workstation-type notebook computer of claim 1 wherein said large-scaled display monitor is a television set.

9. The workstation-type notebook computer of claim 1 wherein said large-scaled display monitor is a cathode-ray tube display monitor, or a display monitor of any other kind.
